(19) United States
(12) Patent Application Publication
(10) Pub. No.: US 2026/0068652 A1
(43) Pub. Date: Mar. 5, 2026

(54) CAPACITOR IN BONDING STRUCTURE

(71) Applicant: Taiwan Semiconductor Manufacturing Company, Ltd., Hsinchu (TW)

(72) Inventors: Chieh-En Chen, Tainan City (TW); Chen-Hsien Lin, Tainan City (TW); Shyh-Fann Ting, Tainan City (TW)

(21) Appl. No.: 18/820,850

(22) Filed: Aug. 30, 2024

(51) Int. Cl. H01L 23/522; H01L 23/00; H01L 23/528; H01L 25/065; H01L 25/18

(52) U.S. Cl. CPC H01L 23/5223

(57) ABSTRACT

An integrated chip includes a first chip and a second chip bonded to the first chip. The first chip includes a first substrate, a first transistor along the first substrate, a first interconnect over the first transistor, and a first bonding pad over the first interconnect. The second chip includes a second substrate, a second transistor along the second substrate, a second interconnect under the second transistor, and a second bonding pad under the second interconnect. The second bonding pad is bonded to the first bonding pad. The first chip further includes a trench capacitor over the first interconnect and under the first bonding pad. The trench capacitor includes a bottom electrode, a top electrode, and an insulator layer between the bottom and top electrodes. The first bonding pad extends from the second bonding pad to the top electrode of the trench capacitor.

### BACKGROUND

Many modern integrated chips include transistors as well as passive devices. Some examples of passive devices include capacitors, resistors, inductors, varactors, etc. Passive devices are widely used to control integrated chip characteristics, such as gains, time constants, etc. Some passive devices include integrated passive devices (IPDs). An IPD is a collection of one or more passive devices embedded into a single monolithic device and packaged as an integrated circuit (IC).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of an integrated chip including a trench capacitor in a first bonding structure.

FIGS. 2-5 illustrate cross-sectional views of some embodiments of a portion of the integrated chip of FIG. 1.

FIG. 6 illustrates a cross-sectional view of some other embodiments of the integrated chip of FIG. 1.

FIGS. 7-8 illustrate cross-sectional views of some embodiments of a portion of the integrated chip of FIG. 6.

FIG. 9 illustrates a cross-sectional view of some other embodiments of the integrated chip of FIG. 1.

FIG. 10 illustrates a cross-sectional view of some other embodiments of the integrated chip of FIG. 1.

FIGS. 11-12 illustrate cross-sectional views of some embodiments of a portion of the integrated chip of FIG. 10.

FIGS. 13-42 illustrate cross-sectional views of some embodiments of a method for forming an integrated chip including a trench capacitor in a first bonding structure.

FIG. 43 illustrates a flow diagram of some embodiments of a method for forming an integrated chip including a trench capacitor in a bonding structure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An integrated chip includes a first chip and a second chip bonded to the first chip. The first chip includes a first transistor along a first semiconductor substrate, a first interconnect over and coupled to the first transistor, and a first bonding structure over the first interconnect. The second chip includes a second bonding structure over and bonded to the first bonding structure, a second conductive interconnect over the second bonding structure, a second semiconductor substate over the second interconnects, a photodetector along the second semiconductor substrate, and a second transistor along the second semiconductor substrate. In some integrated chips, the second transistor is a transfer transistor which includes a transfer gate between a floating diffusion region and the photodetector.

The first chip further includes a trench capacitor. In some integrated chips, the trench capacitor is below the first bonding structure and a thick metal interconnect is arranged and coupled between a top electrode of the trench capacitor and the first bonding structure. A challenge with these integrated chips is that the thick metal interconnect can increase a parasitic capacitance of the floating diffusion region of the second chip. Consequently, a performance of the integrated chip may be reduced. For example, a conversion gain of the photodetector may be reduced and/or a noise of the photodetector may be increased. Further, because the metal interconnect between the trench capacitor and the first bonding structure is thick, a cost of forming the integrated chip may be increased.

In various embodiments of the present disclosure, the trench capacitor is within the first bonding structure and the first chip is devoid of the thick metal interconnect. By disposing the trench capacitor within the bonding structure and removing the thick metal interconnect, a parasitic capacitance of the floating diffusion region can be reduced. Thus, a performance of the integrated chip can be improved. For example, a conversion gain of the integrated chip may be improved and/or a noise of the integrated chip may be reduced. Further, by removing the thick metal interconnect from between the trench capacitor and the first bonding structure, a cost of forming the integrated chip can be reduced. Furthermore, removing the large interconnect may allow for a pitch of the integrated chip to be reduced.

FIG. 1 illustrates a cross-sectional view 100 of some embodiments of an integrated chip including a trench capacitor 135 in a first bonding structure 186.

The integrated chip includes a first chip 102 and a second chip 104 bonded over the first chip 102. The first chip 102 includes a first semiconductor substrate 106 and a first plurality of transistors (e.g., transistor 108 and transistor 110) along the first semiconductor substrate 106. A first dielectric structure 118 comprising a plurality of dielectric layers and a plurality of etch stop layers is over the first semiconductor substrate 106. A first plurality of conductive interconnects (e.g., contacts 120, 121, conductive lines 122, 123, 126, 127, and conductive vias 124, 125) are over the first semiconductor substrate 106 and within the first dielectric structure 118.

A first bonding structure 186 is over the first dielectric structure 118 and the first conductive interconnects 120-127. The first bonding structure 186 includes a first bonding dielectric structure 128, a first plurality of bonding contacts (e.g., bonding contact 130), and a first plurality of bonding pads (e.g., bonding pad 132 and bonding pad 134). The first bonding dielectric structure 128 comprises one or more dielectric layers and one or more etch stop layers. Bonding contact 130 is within the first bonding dielectric structure 128 and extends from bonding pad 134 to the conductive line 127. Bonding pad 134 and bonding pad 132 are within the first bonding dielectric structure 128.

The second chip 104 includes an image sensor along a second semiconductor substrate 164. The image sensor includes a plurality of photodetectors 178 in the second semiconductor substrate 164 and a plurality of transfer transistors (e.g., transfer transistor 160 and transfer transistor 162) along the second semiconductor substrate 164. Transfer transistors 160, 162 include gate electrodes 170 between photodiode regions 166 and a floating diffusion region 168. A second dielectric structure 144 comprising a plurality of dielectric layers and a plurality of etch stop layers is under the second semiconductor substrate 164. A second plurality of conductive interconnects (e.g., contacts 158, 159, conductive lines 153, 154, 156, 157, and conductive via 155) are under the second semiconductor substrate 164 and within the second dielectric structure 144.

A second bonding structure 188 is under the second dielectric structure 144 and the second conductive interconnects 153-159. The second bonding structure 188 includes a second bonding dielectric structure 142, a second plurality of bonding contacts (e.g., bonding contact 150 and boding contact 152), and a second plurality of bonding pads (e.g., bonding pad 146 and bonding pad 148). The second bonding dielectric structure 142 comprises one or more dielectric layers and one or more etch stop layers. Bonding contact 150, 152 are within the second bonding dielectric structure 142 and extend from bonding pads 146, 148 to conductive lines 153, 154, respectively. Bonding pads 146 and bonding pad 148 are within the second bonding dielectric structure 142.

The first chip 102 and the second chip 104 are bonded together along a bonding interface 180. For example, the second bonding dielectric structure 142 and the first bonding dielectric structure 128 are bonded together along the bonding interface 180. Bonding pad 132 and bonding pad 146 are bonded together along the bonding interface 180. Bonding pad 134 and bonding pad 148 are bonded together along the bonding interface 180.

The first chip 102 further includes a trench capacitor 135 within the first bonding structure 186. The trench capacitor 135 is within the first bonding dielectric structure 128 at the bonding contact level. For example, the trench capacitor 135 is over the conductive interconnects 120-127 of the first chip 102, below the bonding pads of the first chip 102, and laterally spaced from the bonding contacts of the first chip 102. The trench capacitor 135 includes a bottom electrode 136, a top electrode 140, and an insulator layer 138 between the bottom electrode 136 and the top electrode 140. The bottom electrode 136 directly contacts conductive line 126. The top electrode 140 directly contacts bonding pad 132. Bonding pad 132 extends from the top electrode 140, through the first bonding dielectric structure 128, to bonding pad 146.

By disposing the trench capacitor 135 within the first bonding structure 186 at the bonding contact level, a performance of the integrated chip can be improved. For example, the length of the current path from the floating diffusion region 168 on the second chip 104 to transistor 110 on the first chip 102 can be reduced. Reducing the length of current path can reduce a parasitic capacitance at the floating diffusion region 168. Reducing the parasitic capacitance can reduce the noise and improve the conversion gain of the image sensor on the second chip 104.

Further, by disposing the trench capacitor 135 within the first bonding structure 186 at the bonding contact level, a cost of forming the integrated chip can be reduced. For example, by forming the trench capacitor 135 within the first bonding structure 186 instead of forming a thick interconnect between the trench capacitor 135 and the first bonding structure 186, the amount of conductive material required to form the integrated chip can be reduced, the number of masks needed to form the integrated chip can be reduced, and/or the time required to form the integrated chip can be reduced.

Furthermore, by avoiding the large interconnect between the trench capacitor 135 and the first bonding structure 186, a pitch of the integrated chip may be reduced.

In some embodiments, transistors 108, 110 of the first chip 102 are pixel transistors (e.g., source follower transistors, reset transistors, select transistors, or the like) corresponding to the photodetectors 178 of the second chip 104 and are coupled to the photodetectors by some of the first interconnects 120-127, some of the second interconnects 153-159, and the bonding structures 186, 188. In some other embodiments, the second chip 104 includes pixel transistors 182, 184 (e.g., source follower transistors, reset transistors, select transistors, or the like) corresponding (and coupled) to the photodetectors 178 along the second semiconductor substrate 164 and beside the transfer transistors 160, 162. In some such embodiments, the first chip 102 is an application specific integrated circuit (ASIC) chip (e.g., transistors 108, 110 are ASIC transistors) and the integrated chip includes a two-chip (e.g., two wafer, two die, etc.) stack.

In some embodiments, transistors 108, 110 include source/drains regions 112 and gate electrodes 114. Source/drain region(s) may refer to a source or a drain, individually or collectively dependent upon the context. In some embodiments, shallow trench isolation structures 116 are between transistors of the first chip 102. In some embodiments, deep trench isolation structure 172 are between photodetectors 178 of the second chip 104. Color filters 174 and micro lenses 176 are over the photodetectors 178. In some embodiments, a single color filter 174 and a single micro lens 176 are over two or more photodetectors 178. In some other embodiments, each photodetector 178 has a corresponding color filter 174 and micro lens 176 as illustrated, for example, in FIG. 9.

In some embodiments, the first semiconductor substrate 106 and/or the second semiconductor substrate 164 comprise silicon or some other suitable material. In some embodiments, the dielectric layers and etch stop layers of the first dielectric structure 118 and/or the second dielectric structure 144 comprise silicon dioxide, silicon nitride, silicon carbide, aluminum oxide, hafnium oxide, or some other suitable material. In some embodiments, the conductive interconnects 120-127, 153-159 comprise copper, tungsten, aluminum, or some other suitable material.

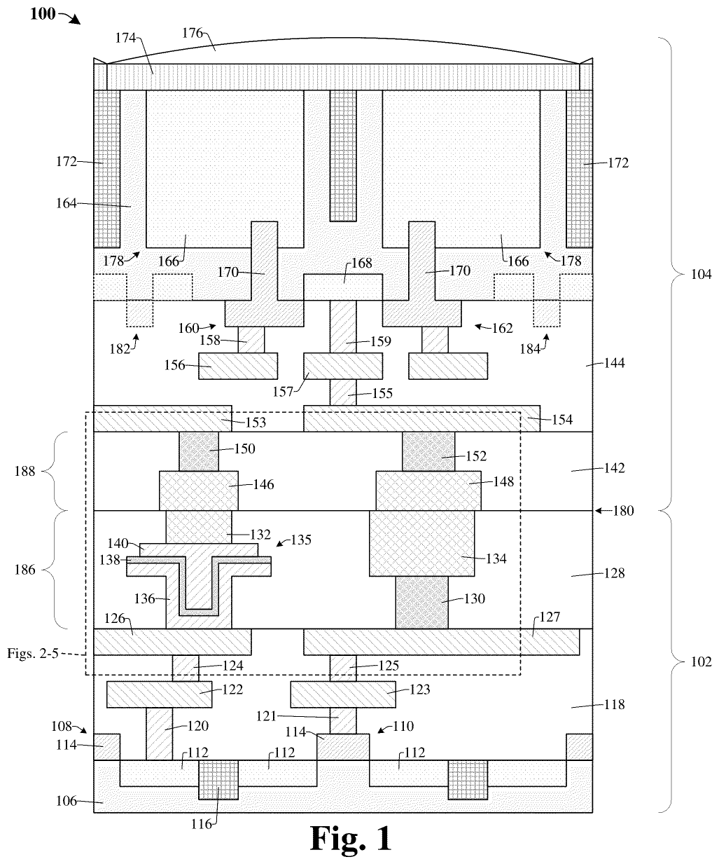

FIG. 2 illustrates a cross-sectional view 200 of some embodiments of a portion of the integrated chip of FIG. 1.

The first bonding dielectric structure 128 includes a first etch stop layer 204 over the first dielectric structure 118, a first dielectric layer 206 over the first etch stop layer 204, a second etch stop layer 208 over the first dielectric layer 206, a second dielectric layer 210 over the second etch stop layer 208, a third etch stop layer 212 over the second etch stop layer 208 and within the second dielectric layer 210, and a first bonding dielectric layer 222 over the second dielectric layer 210. The first etch stop layer 204 extends along tops of the first dielectric structure 118 and conductive lines 126, 127. In some embodiments, etch stop layer 208 and etch stop layer 212 comprise different dielectric(s) than dielectric layer 206 and dielectric layer 210. In some embodiments, the first bonding dielectric layer 222 comprises different dielectric(s) than dielectric layers 206, 210 and etch stop layers 208, 212.

Bonding contact 130 extends vertically through the first etch stop layer 204 and the first dielectric layer 206 from conductive line 127 to bonding pad 134. The trench capacitor 135 extends vertically through the second etch stop layer 208, the first dielectric layer 206, and the first etch stop layer 204. The bottom electrode 136 extends laterally along a top surface of the second etch stop layer 208 and a top surface of conductive line 126. The bottom electrode 136 extends vertically along sidewalls of etch stop layer 208, sidewalls of dielectric layer 206, and sidewalls of etch stop layer 204. The insulator layer 138 extends laterally along a top surface of the bottom electrode 136 and an upper surface of the bottom electrode 136, and vertically along sidewalls of the bottom electrode. The top electrode 140 extends laterally along a top surface of the insulator layer 138 and an upper surface of the insulator layer 138, and vertically along sidewalls of the insulator layer 138. Outermost sidewalls of the top electrode 140 are laterally offset from outermost sidewalls of the bottom electrode 136 and outermost sidewalls of the insulator layer 138. The third etch stop layer 212 extends along a top surface of the top electrode 140 from a first outermost sidewall of the top electrode 140 to a second outermost sidewall of the top electrode 140. The second dielectric layer 210 is over the trench capacitor 135 and on opposite sides of an upper portion of the trench capacitor 135.

Bonding pad 134 extends through the second etch stop layer 208, the second dielectric layer 210, and the first bonding dielectric layer 222 from bonding contact 130 to bonding pad 148. Bonding pad 132 extends through the third etch stop layer 212, the second dielectric layer 210, and the first bonding dielectric layer 222 from the top electrode 140 to bonding pad 146.

The second bonding dielectric structure 142 includes a second bonding dielectric layer 224, a third dielectric layer 214 over the second bonding dielectric layer 224, a fourth etch stop layer 216 over the third dielectric layer 214, a fourth dielectric layer 218 over the fourth etch stop layer 216, and a fifth etch stop layer 220 over the fourth dielectric layer 218. In some embodiments, etch stop layer 216 comprises different dielectric(s) than dielectric layer 214 and dielectric layer 218. In some embodiments, the second bonding dielectric layer 224 comprises different dielectric(s) than dielectric layers 214, 218 and etch stop layer 216.

Bonding pad 146 extends through the second bonding dielectric layer 224, dielectric layer 214, and etch stop layer 216 from bonding pad 132 to bonding contact 150. Bonding pad 148 extends through the second bonding dielectric layer 224, dielectric layer 214, and etch stop layer 216 from bonding pad 134 to bonding contact 152.

Bonding contact 150 extends through dielectric layer 218 and etch stop layer 220 from bonding pad 146 to conductive line 153. Bonding contact 152 extends through dielectric layer 218 and etch stop layer 220 from bonding pad 148 to conductive line 154.

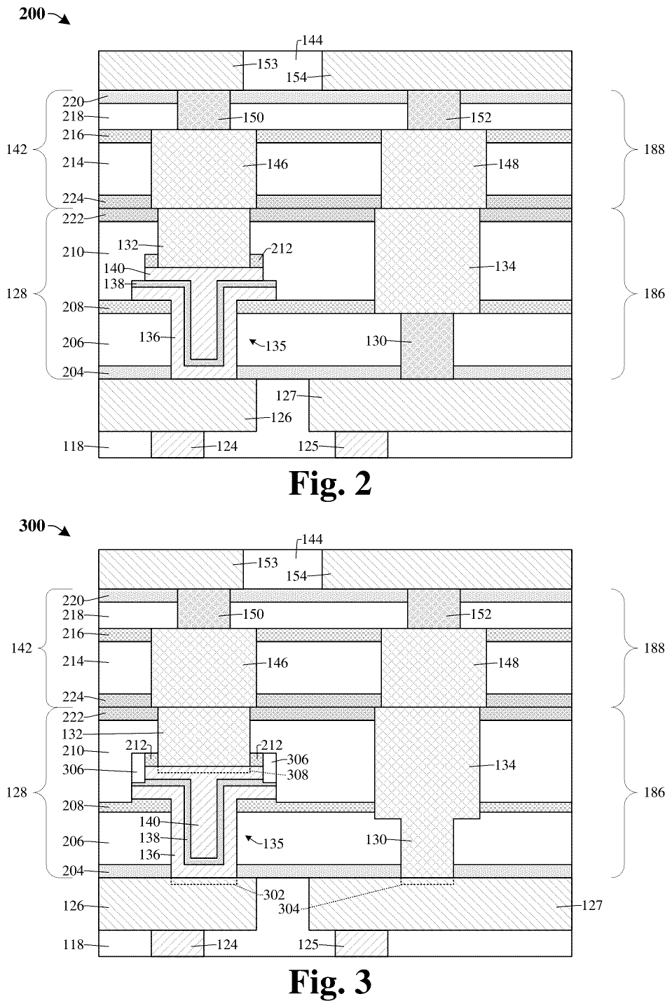

FIG. 3 illustrates a cross-sectional view 300 of some other embodiments of the integrated chip of FIG. 2.

In some embodiments, the bottom electrode 136 of the trench capacitor 135 extends below etch stop layer 204 into conductive line 126, as illustrated by dashed line 302. Similarly, in some embodiments, bonding contact 130 extends below etch stop layer 204 into conductive line 127, as illustrated by dashed line 304.

In some embodiments, the bottom surface of dielectric layer 210 is on a topmost surface of etch stop layer 208. In some other embodiments, the bottom surface of dielectric layer 210 is on an upper surface of etch stop layer 208 that is below the topmost surface of etch stop layer 208. In some embodiments, the first bonding dielectric structure 128 further comprises a dielectric layer 306 over the insulator layer 138 and the bottom electrode 136 along outermost sidewalls of the top electrode 140 and etch stop layer 212. Dielectric layer 210 is over and on opposite sides of dielectric layer 306. In some embodiments, the bottommost surface of dielectric layer 306 is on a topmost surface of insulator layer 138. In some other embodiments, the bottommost surface of dielectric layer 306 is on an upper surface of insulator layer 138 that is below the topmost surface of insulator layer 138. In some embodiments, dielectric layer 306 comprises different dielectric(s) than etch stop layer 208 and etch stop layer 212.

In some embodiments, bonding pad 132 extends below etch stop layer 212 into top electrode 140, as illustrated by dashed line 308. In some embodiments, bonding pad 134 extends below etch stop layer 208 into dielectric layer 206. In some embodiments, bonding pad 134 and bonding contact 130 are formed together with a dual damascene process and comprise a same material.

In some embodiments, any of dielectric layer 206, dielectric layer 210, dielectric layer 306, dielectric layer 214, and dielectric layer 218 comprise silicon dioxide or some other suitable material. In some embodiments, etch stop layer 204 and/or etch stop layer 220 comprises silicon carbide or some other suitable material. In some embodiments, any of etch stop layer 208, etch stop layer 212, and etch stop layer 216 comprise silicon nitride or some other suitable material. In some embodiments, the first bonding dielectric layer 222 and/or the second bonding dielectric layer 224 comprise silicon oxynitride or some other suitable material.

In some embodiments, any of bonding contact 130, bonding contact 150, bonding contact 152, bonding pad 132, bonding pad 134, bonding pad 146, and bonding pad 148 comprise copper or some other suitable material.

In some embodiments, the bottom electrode 136 comprises a different conductive material than the top electrode 140. In some embodiments, the bottom electrode 136 comprises titanium nitride, tantalum, tantalum nitride, a combination of the foregoing, or some other suitable material. In some embodiments, top electrode 140 comprises titanium nitride or some other suitable material. In some embodiments, insulator layer 138 comprises a high-k dielectric (e.g., aluminum oxide, hafnium oxide, zirconium oxide, or the like) or some other suitable material.

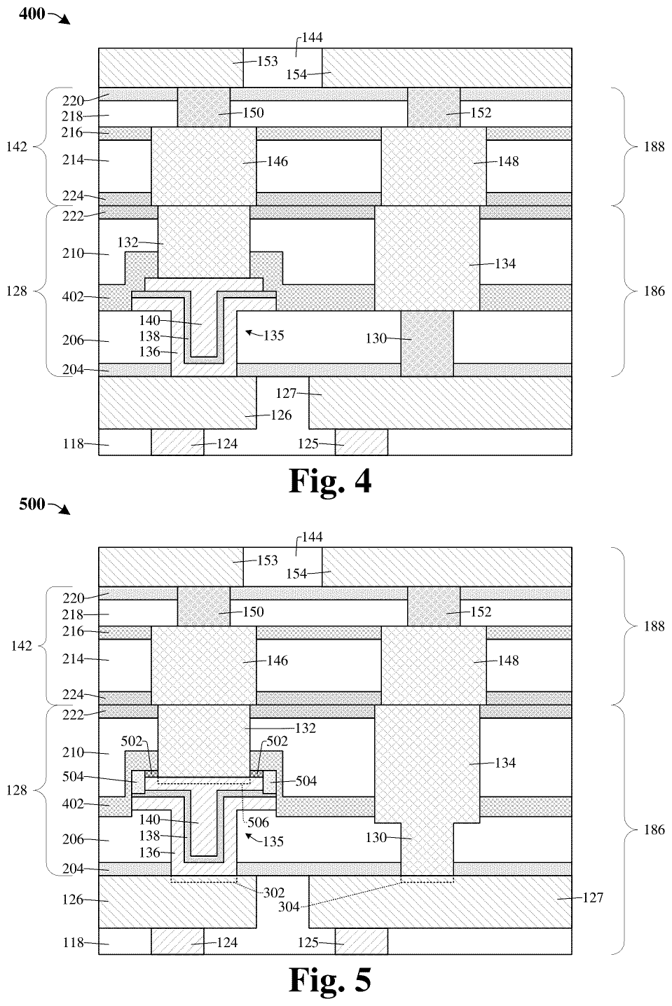

FIG. 4 illustrates a cross-sectional view 400 of some other embodiments of a portion of the integrated chip of FIG. 1.

The first bonding dielectric structure 128 includes an etch stop layer 402 between dielectric layer 206 and dielectric layer 210. Etch stop layer 402 extends along a top surface of dielectric layer 206 and covers a top portion of the trench capacitor 135. For example, etch stop layer 402 covers outermost sidewalls of the bottom electrode 136, the insulator layer 138, and the top electrode 140 and further covers a top surface of the insulator layer 138 and a top surface of the top electrode 140. Bonding pad 132 extends through etch stop layer 402 to the top electrode 140. Bonding pad 134 extends through etch stop layer 402 to dielectric layer 206 and bonding contact 130. In some embodiments, etch stop layer 402 comprises different dielectric(s) than dielectric layer 206 and dielectric layer 210.

FIG. 5 illustrates a cross-sectional view 500 of some other embodiments of the integrated chip of FIG. 4.

In some embodiments, a bottommost surface of etch stop layer 402 is on a topmost surface of dielectric layer 206. In some other embodiments, a bottommost surface of etch stop layer 402 is on an upper surface of dielectric layer 206 that is below the topmost surface of dielectric layer 206 on opposite sides of the trench capacitor 135.

In some embodiments, the first bonding dielectric structure 128 further includes an etch stop layer 502 on a top surface of the top electrode 140 and a dielectric layer 504 covering outermost sidewalls of the top electrode 140 and dielectric layer 504. In some embodiments, a bottommost surface of dielectric layer 504 is on a topmost surface of insulator layer 138. In some other embodiments, a bottommost surface of dielectric layer 504 is on an upper surface of insulator layer 138 that is below the topmost surface of insulator layer 138. Etch stop layer 402 covers sidewalls of dielectric layer 504, a top surface of dielectric layer 504, and a top surface of etch stop layer 502. In some embodiments, etch stop layer 502 comprises different dielectric(s) than dielectric layer 206 and dielectric layer 210. In some embodiments, dielectric layer 504 comprises different dielectric(s) than etch stop layer 402 and etch stop layer 502.

Bonding pad 132 extends through etch stop layer 402 and through etch stop layer 502 to the top electrode 140. In some embodiments, bonding pad 132 extends below etch stop layer 502 into top electrode 140, as illustrated by dashed line 506. In some embodiments, bonding pad 134 extends below etch stop layer 402 into dielectric layer 206.

In some embodiments, any of etch stop layer 402, etch stop layer 502, and dielectric layer 504 comprise silicon nitride or some other suitable material.

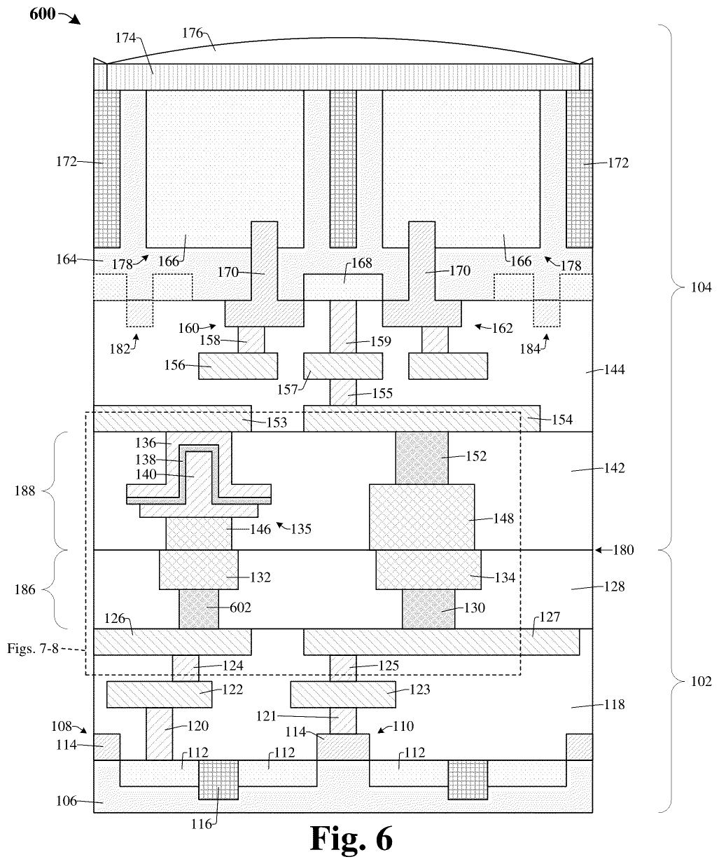

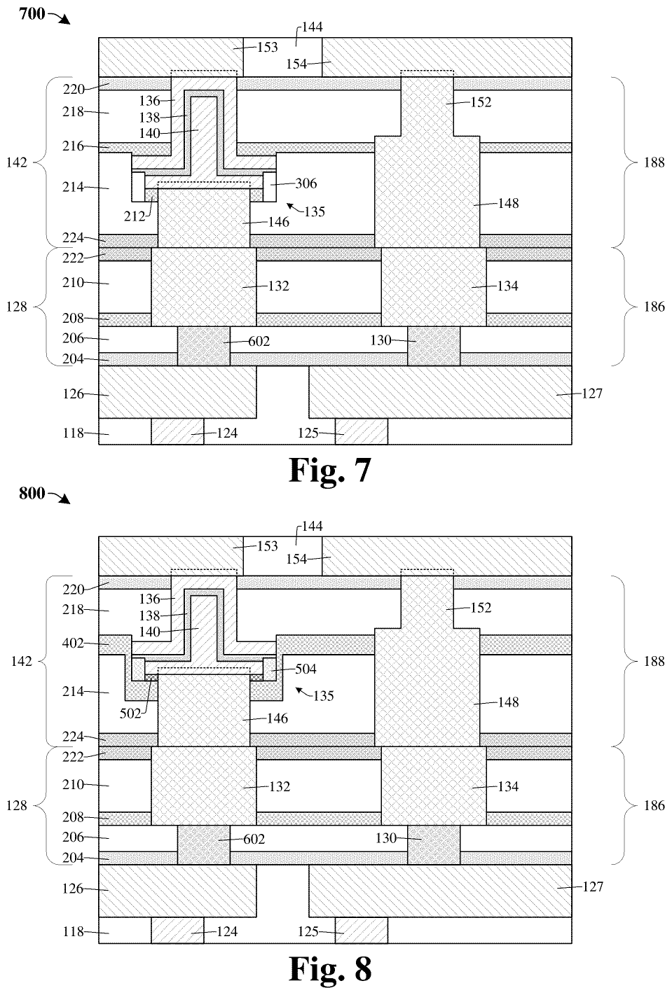

FIG. 6 illustrates a cross-sectional view 600 of some embodiments of the integrated chip of FIG. 1 in which the trench capacitor 135 is in the second chip 104. FIGS. 7-8 illustrate cross-sectional views 700-800 of some embodiments of a portion of the integrated chip of FIG. 6.

The trench capacitor 135 is on the second chip 104 and within the second dielectric structure 144. The trench capacitor 135 has a “flipped” orientation relative to FIG. 1 and thus the bottom electrode 136 is over the insulator layer 138 and the top electrode 140. Conductive line 153 is on the bottom electrode 136. The top electrode 140 is on bonding pad 146 and laterally spaced from bonding contact 152. A bonding contact 602 extends from bonding pad 132 to conductive line 126.

The trench capacitor 135 is within dielectric layer 214 and extends through etch stop layer 216, dielectric layer 218, and etch stop layer 220. The second bonding dielectric structure 142 includes dielectric layer 306 and etch stop layer 212 within dielectric layer 214.

In some embodiments, the integrated chip of FIG. 6 further includes a second trench capacitor on the first chip 102 (e.g., as illustrated in FIG. 1) so that the integrated chip includes a trench capacitor on the first chip 102 and a trench capacitor on the second chip 104. In some embodiments, the second trench capacitor (on the first chip 102) is coupled to the trench capacitor 135 (on the second chip 104). For example, in some embodiments, bonding pad 132 is on the top electrode of the second trench capacitor (e.g., as illustrated in FIG. 1) so that bonding pad 132 and bonding pad 146 couple the top electrodes of the two capacitors together. In some other embodiments, the second trench capacitor is not directly coupled to trench capacitor 135 at the bonding interface 180. For example, in some embodiments, bonding pad 134 is on the top electrode of the second trench capacitor.

In some embodiments, transistors 108, 110 of the first chip 102 are pixel transistors corresponding (and coupled) to the photodetectors 178 of the second chip 104. In some other embodiments, the second chip 104 includes pixel transistors 182, 184 corresponding (and coupled) to the photodetectors 178 along the second semiconductor substrate 164. In some such embodiments, the first chip 102 is an ASIC chip (e.g., transistors 108, 110 are ASIC transistors) and the integrated chip includes a two-chip (e.g., two wafer, two die, etc.) stack.

FIG. 9 illustrates a cross-sectional view 900 of some embodiments of the integrated chip of FIG. 1 in which a third chip 902 is bonded to the first chip 102.

The first chip 102 is over the third chip 902. The third chip 902 includes a third semiconductor substrate 904 and a third plurality of transistors (e.g., transistor 908) along the third semiconductor substrate 904. A third dielectric structure 910 comprising a plurality of dielectric layers and a plurality of etch stop layers is over the third semiconductor substrate 904. A third plurality of conductive interconnects (e.g., contact 912, conductive line 914, and conductive vias) are over the third semiconductor substrate 904 and within the third dielectric structure 910. A third bonding dielectric structure 920 is over the third dielectric structure 910. A third plurality of bonding conductive pads (e.g., bonding pad 918) and a third plurality of bonding contacts (e.g., bonding contact 916) are within the third bonding dielectric structure 920.

The first chip 102 further includes a fourth bonding dielectric structure 922 along a backside of the first semiconductor substrate 106, bonding pad 924 and bonding contact 934 within bonding dielectric structure 922, a through substrate via (TSV) 928 extending through the first semiconductor substrate 106 from a conductive interconnect 930 within the first dielectric structure 118 to bonding contact 934, and a dielectric liner 926 surrounding the TSV 928. Bonding dielectric structure 922 is bonded to bonding dielectric structure 920 along a bonding interface 932. Bonding pad 924 is bonded to bonding pad 918 along bonding interface 932.

In some embodiments, the integrated chip of FIG. 9 further includes a second trench capacitor on the second chip 104 (e.g., as illustrated in FIG. 6) so that the integrated chip includes a trench capacitor on the first chip 102 and a trench capacitor on the second chip 104.

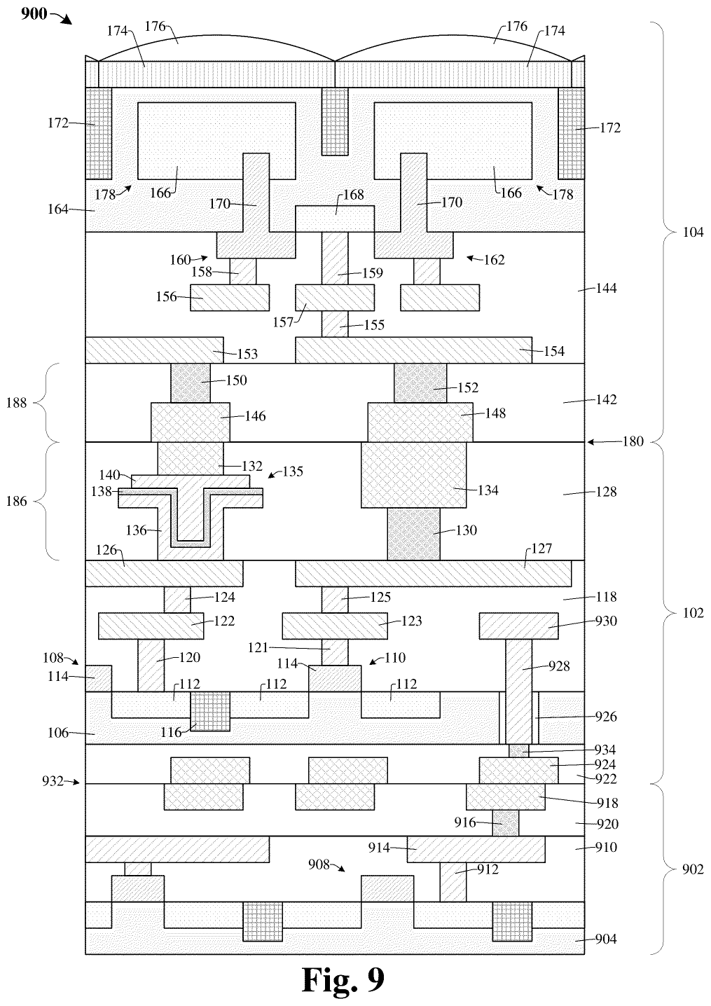

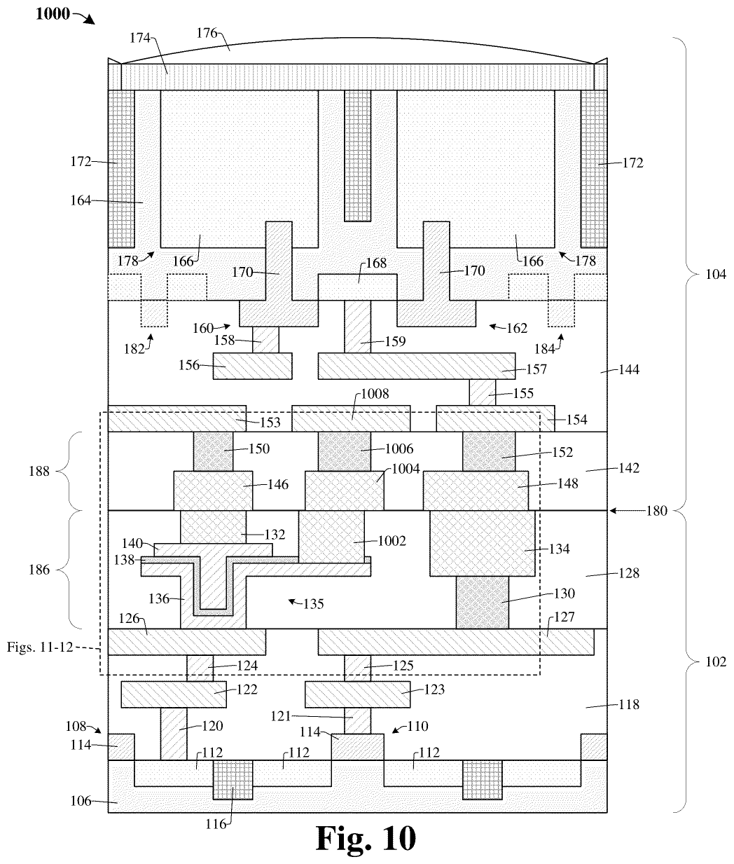

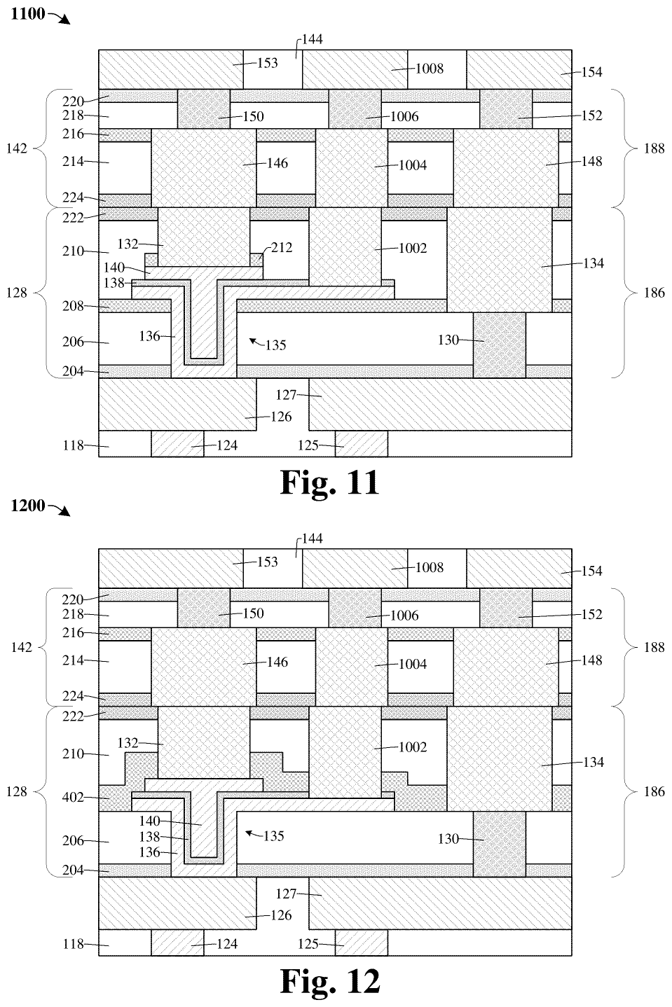

FIG. 10 illustrates a cross-sectional view 1000 of some embodiments of the integrated chip of FIG. 1 in which a bonding pad 1002 is on the bottom electrode 136 of the trench capacitor 135. FIGS. 11-12 illustrate cross-sectional views 1100-1200 of some embodiments of a portion of the integrated chip of FIG. 10.

The first chip 102 includes bonding pad 1002. Bonding pad 1002 is laterally spaced between bonding pad 132 and bonding pad 134. The second chip 104 includes a bonding pad 1004, a conductive interconnect 1008 over the bonding pad 1004, and a bonding contact 1006 extending from bonding pad 1004 to conductive interconnect 1008.

Bonding pad 1002 is bonded to bonding pad 1004 along the bonding interface 180. Bonding pad 1002 extends through the first bonding dielectric layer 222, the first bonding dielectric structure 128, and the insulator layer 138 from bonding pad 1004 to the bottom electrode 136 of the trench capacitor 135. Thus, both electrodes of the trench capacitor 135 on the first chip 102 are coupled to the interconnect structure on the second chip 104.

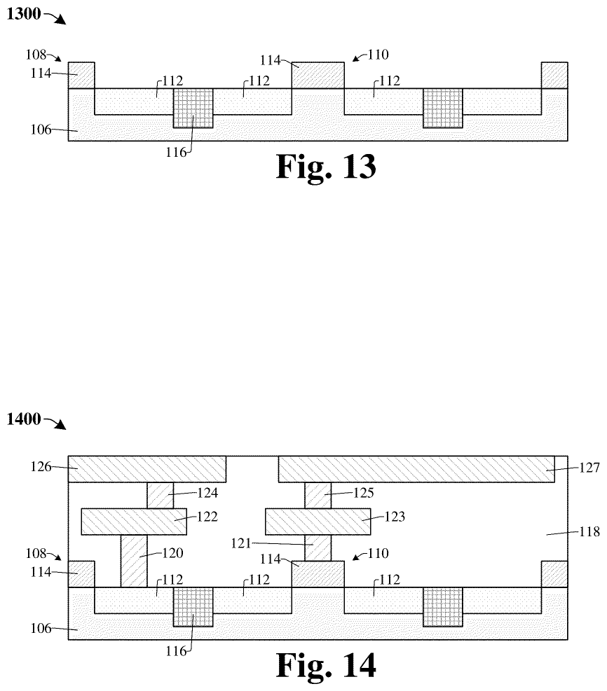

FIGS. 13-42 illustrate cross-sectional views 1300-4200 of some embodiments of a method for forming an integrated chip including a trench capacitor 135 in a first bonding structure 186. Although FIGS. 13-42 are described in relation to a method, it will be appreciated that the structures disclosed in FIGS. 13-42 are not limited to such a method, but instead may stand alone as structures independent of the method.

As shown in cross-sectional view 1300 of FIG. 13, a plurality of transistors (e.g., transistor 108 and transistor 110) comprising source/drain regions 112 and gate electrodes 114 are formed along a first semiconductor substrate 106. Shallow trench isolation (STI) structures 116 are formed between the transistors.

As shown in cross-sectional view 1400 of FIG. 14, a first dielectric structure 118 and a first plurality of conductive interconnects (e.g., contacts 120, 121, conductive lines 122, 123, 126, 127, and conductive vias 124, 125) are formed over the first semiconductor substrate 106.

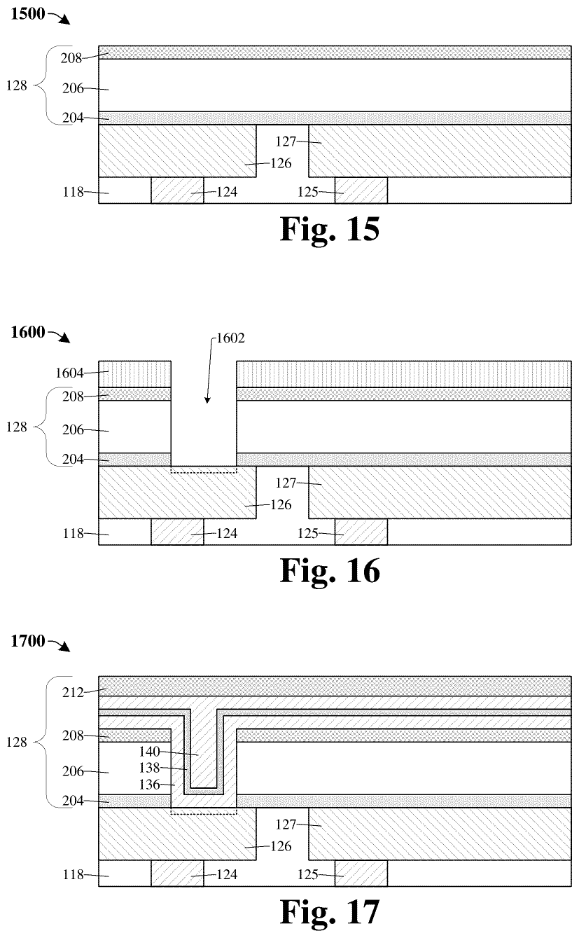

FIGS. 15-26 illustrate cross-sectional views 1500-2600 of some embodiments of a method for forming the first bonding structure 186 over the first dielectric structure 118 and the first conductive interconnects 120-127.

As shown in cross-sectional view 1500 of FIG. 15, an etch stop layer 204 is deposited over the first dielectric structure 118 and conductive lines 126, 127. A dielectric layer 206 is deposited over etch stop layer 204. An etch stop layer 208 is deposited over dielectric layer 206. In some embodiments, conductive lines 126, 127 comprise copper, aluminum, tungsten, or some other suitable material. In some embodiments, etch stop layer 204 comprises silicon carbide or some other suitable material and is deposited by a chemical vapor deposition (CVD) process, a physical vapor deposition (PVD) process, or an atomic layer deposition (ALD) process. In some embodiments, dielectric layer 206 comprises silicon dioxide or some other suitable material and is deposited by a CVD process, a PVD process, an ALD process, or some other suitable process. In some embodiments, etch stop layer 208 comprises silicon nitride or some other suitable material and is deposited by a CVD process, a PVD process, an ALD process, or some other suitable process.

As shown in cross-sectional view 1600 of FIG. 16, etch stop layer 208, dielectric layer 206, and etch stop layer 204 are etched to form a trench 1602 therein. In some embodiments, a masking layer 1604 (e.g., a photoresist layer, a hard mask layer, or the like) is formed over etch stop layer 208 and the etching is performed according to the masking layer 1604. In some embodiments, the etching comprises a dry etching process (e.g., a plasma etching process, a reactive ion etching process, an ion beam etching process, or the like) or some other suitable process. In some embodiments, the etching extends into conductive line 126, as shown by the dashed line below the trench 1602. In some embodiments, masking layer(s) are removed after etching.

As shown in cross-sectional view 1700 of FIG. 17, a bottom electrode 136 is deposited over etch stop layer 208 and in the trench 1602. An insulator layer 138 is deposited over the bottom electrode 136 and in the trench 1602. A top electrode 140 is deposited over the insulator layer 138 and in the trench 1602. An etch stop layer 212 is deposited over the top electrode 140.

In some embodiments, the bottom electrode 136 comprises titanium nitride, tantalum, tantalum nitride, a combination of the foregoing, or some other suitable material and is deposited by a CVD process, a PVD process, an ALD process, or some other suitable process. In some embodiments, the insulator layer 138 comprises a high-k dielectric (e.g., aluminum oxide, hafnium oxide, zirconium oxide, or the like) or some other suitable material and is deposited by a CVD process, a PVD process, an ALD process, or some other suitable process. In some embodiments, the top electrode 140 comprises titanium nitride or some other suitable material and is deposited by a CVD process, a PVD process, an ALD process, or some other suitable process. In some embodiments, etch stop layer 212 comprises silicon nitride or some other suitable material and is deposited by a CVD process, a PVD process, an ALD process, or some other suitable process.

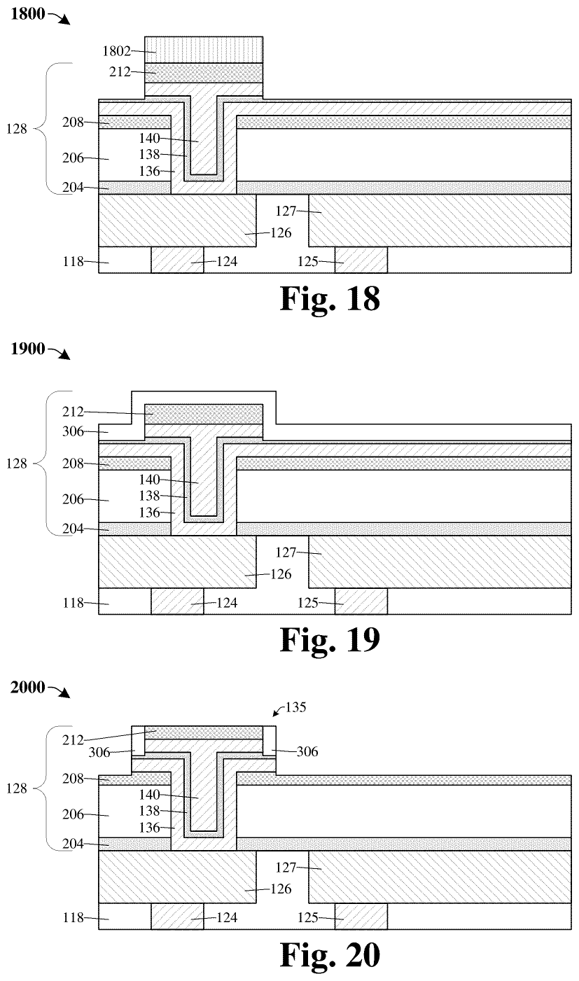

As shown in cross-sectional view 1800 of FIG. 18, etch stop layer 212 and the top electrode 140 are etched to delimit the top electrode 140. In some embodiments, a masking layer 1802 (e.g., a photoresist layer, a hard mask layer, or the like) is formed over etch stop layer 212 and the etching is performed according to the masking layer 1802. In some embodiments, the etching comprises a dry etching process or some other suitable process. The insulator layer 138 acts as an etch stop layer during the etching (e.g., blocks the etching from reaching bottom electrode 136). In some embodiments, the etching extends into the insulator layer 138 but not through the insulator layer 138.

As shown in cross-sectional view 1900 of FIG. 19, a dielectric layer 306 is conformally deposited over the insulator layer 138 and etch stop layer 212. In some embodiments, dielectric layer 306 comprises silicon dioxide or some other suitable material and is deposited by a CVD process, a PVD process, an ALD process, or some other suitable process.

As shown in cross-sectional view 2000 of FIG. 20, dielectric layer 306, insulator layer 138, and bottom electrode 136 are etched to delimit the insulator layer 138 and the bottom electrode 136. The etching comprises a self-aligned etching process where the bottom electrode 136 and the insulator layer 138 are etched on opposite sides of the top electrode 140 without a masking layer. For example, dielectric layer 306 has a greater thickness along sidewalls of the top electrode 140 and sidewalls of etch stop layer 212 where dielectric layer 306 “steps” from the insulator layer 138 to etch stop layer 212 than along a top of etch stop layer 212 and along a top of insulator layer 138. Thus, these “step” regions of dielectric layer 306 remain over the insulator layer 138 and the bottom electrode 136 along the sidewalls of the top electrode 140 and the sidewalls of etch stop layer 212 after the etching process due to the increased thickness at these regions. As a result, the insulator layer 138 and the bottom electrode 136 are self-aligned to the top electrode 140.

During the etching, etch stop layer 212 blocks the etching from reaching the top electrode 140 and etch stop layer 208 blocks the etching from reaching dielectric layer 206. In some embodiments, the etching extends into etch stop layer 212 and etch stop layer 208 but not through these layers. In some embodiments, the etching comprises a dry etching process or some other suitable process.

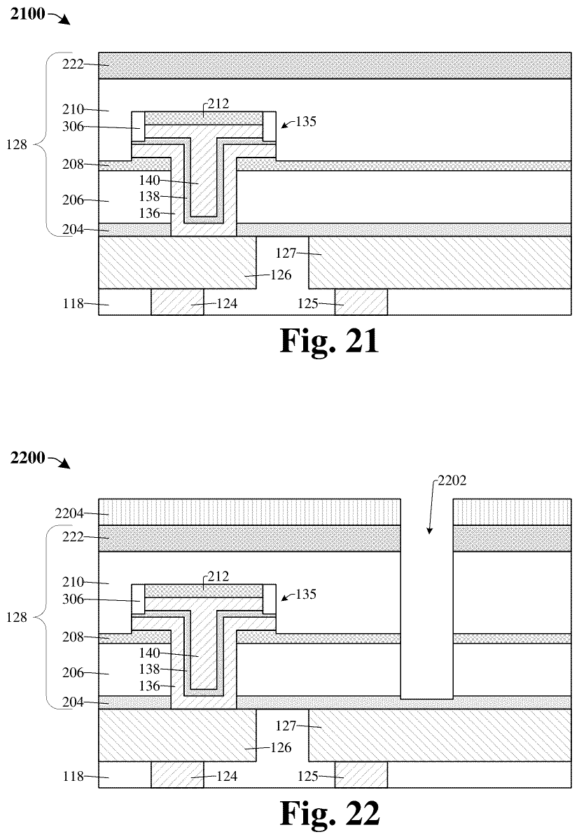

As shown in cross-sectional view 2100 of FIG. 21, a dielectric layer 210 is deposited over etch stop layer 208, dielectric layer 306, and etch stop layer 212. In some embodiments, dielectric layer 210 comprises silicon dioxide or some other suitable material and is deposited by a CVD process, a PVD process, an ALD process, or some other suitable process. In some embodiments, a planarization process (e.g., a chemical mechanical planarization (CMP) process or some other suitable process) is performed on dielectric layer 210 after deposition.

Further, a first bonding dielectric layer 222 is deposited over dielectric layer 210. In some embodiments, the first bonding dielectric layer 222 comprises silicon oxynitride or some other suitable material and is deposited by a CVD process, a PVD process, an ALD process, or some other suitable process.

As shown in cross-sectional view 2200 of FIG. 22, bonding dielectric layer 222, dielectric layer 210, etch stop layer 208, and dielectric layer 206 are etched to form an opening 2202 therein over conductive line 127. In some embodiments, a masking layer 2204 (e.g., a photoresist layer, a hard mask layer, or the like) is formed over bonding dielectric layer 222 and the etching is performed according to the masking layer 2204. In some embodiments, the etching comprises a dry etching process or some other suitable process. Etch stop layer 204 blocks the etching from reaching conductive line 127. In some embodiments, the etching extends into etch stop layer 204 but not through etch stop layer 204.

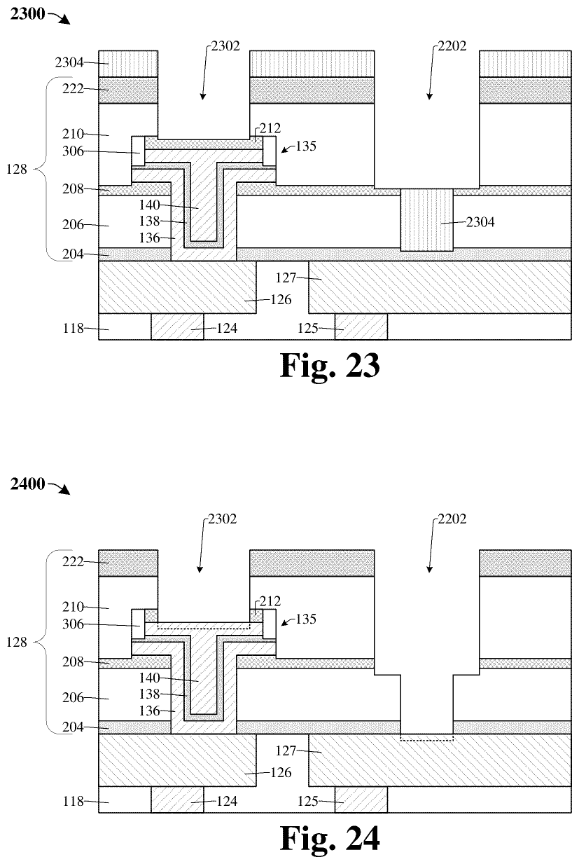

As shown in cross-sectional view 2300 of FIG. 23, bonding dielectric layer 222 and dielectric layer 210 are etched to widen an upper portion of opening 2202 and to form an opening 2302 over the trench capacitor 135. In some embodiments, a masking layer 2304 (e.g., a photoresist layer, a hard mask layer, or the like) is formed over bonding dielectric layer 222 and in a lower portion of opening 2202 and the etching is performed according to the masking layer 2304. In some embodiments, the etching comprises a dry etching process or some other suitable process. Etch stop layer 208 and masking layer 2304 block the etching from extending into dielectric layer 206 at opening 2202. Etch stop layer 212 blocks the etching from reaching the top electrode 140 at opening 2302. In some embodiments, the etching extends into etch stop layer 208 at opening 2202 but not through etch stop layer 208. In some embodiments, the etching extends into etch stop layer 212 at opening 2302 but not through etch stop layer 212.

As shown in cross-sectional view 2400 of FIG. 24, etch stop layer 204 is etched (e.g., by a subsequent etch stop removal etch) to increase the depth of opening 2202 to uncover conductive line 127. Further, etch stop layer 212 is etched (e.g., at the same time and with the same etch stop removal etch) to increase the depth of opening 2302 to uncover the top electrode 140. In some embodiments, the etching extends into conductive line 127 at the lower portion of opening 2202. In some embodiments, the etching extends through etch stop layer 208 and into dielectric layer 206 at the upper portion of opening 2202. In some embodiments, the etching extends into the top electrode 140 at opening 2302.

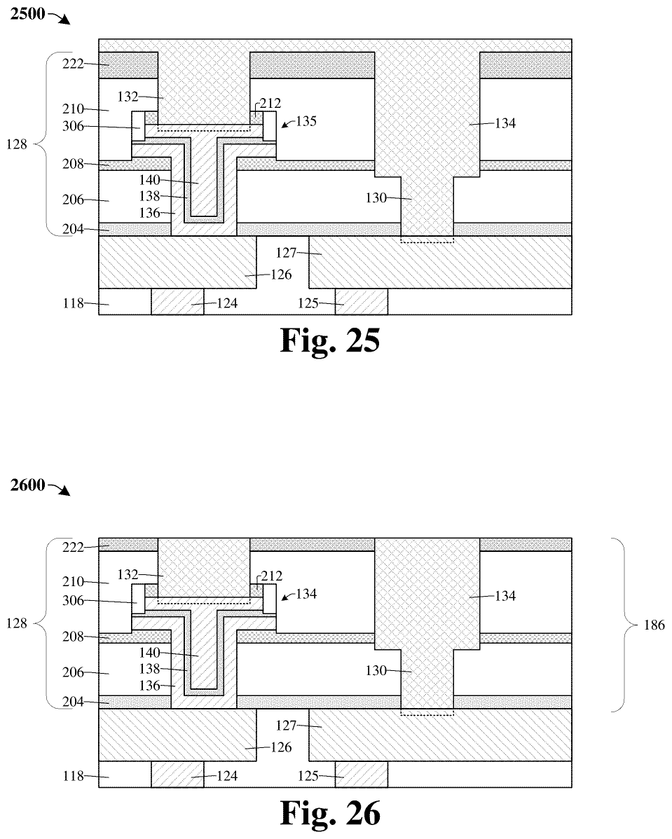

As shown in cross-sectional view 2500 of FIG. 25, a conductive layer is deposited over bonding dielectric layer 222 and in openings 2202, 2302 to form a bonding contact 130 in the lower portion of opening 2202, a bonding pad 134 in the upper portion of opening 2202, and a bonding pad 132 in opening 2302. In some embodiments, the conductive layer comprises copper or some other suitable material and is deposited by a CVD process, a PVD process, an ALD process, or some other suitable process.

As shown in cross-sectional view 2600 of FIG. 26, a planarization process is performed on the conductive layer after deposition to remove the conductive layer from over bonding dielectric layer 222 and to further delimit bonding pads 132, 134. In some embodiments, the planarization process comprises a CMP process, a blanket etching process, or some other suitable process.

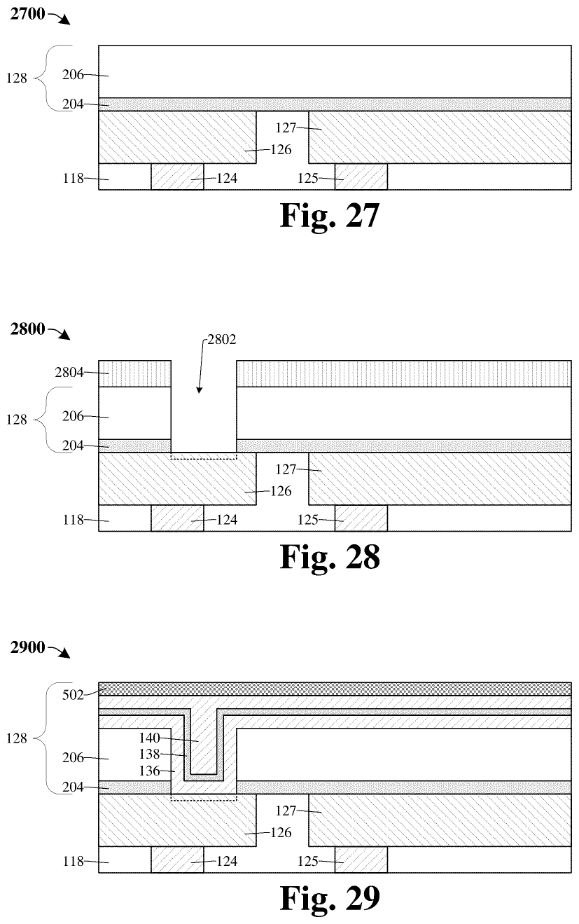

FIGS. 27-39 illustrate cross-sectional views 2700-3900 of some other embodiments of a method for forming the first bonding structure 186 over the first dielectric structure 118 and the first conductive interconnects 120-127.

As shown in cross-sectional view 2700 of FIG. 27, an etch stop layer 204 is deposited over dielectric structure 118 and conductive lines 126, 127. Further, a dielectric layer 206 is deposited over etch stop layer 204.

As shown in cross-sectional view 2800 of FIG. 28, dielectric layer 206 and etch stop layer 204 are etched to form a trench 2802 therein and over conductive line 126. In some embodiments, a masking layer 2804 (e.g., a photoresist layer, a hard mask layer, or the like) is formed over dielectric layer 206 and the etching is performed according to the masking layer 2804. In some embodiments, the etching extends into conductive line 126.

As shown in cross-sectional view 2900 of FIG. 29, a bottom electrode 136 is deposited over dielectric layer 206 and in the trench 2802. An insulator layer 138 is deposited over the bottom electrode 136 and in the trench 2802. A top electrode 140 is deposited over the insulator layer 138 and in the trench 2802. An etch stop layer 502 is deposited over the top electrode 140. In some embodiments, etch stop layer 502 comprises silicon nitride or some other suitable material and is deposited by a CVD process, a PVD process, an ALD process, or some other suitable process.

As shown in cross-sectional view 3000 of FIG. 30, etch stop layer 502 and the top electrode 140 are etched to delimit the top electrode 140. In some embodiments, a masking layer 3002 (e.g., a photoresist layer, a hard mask layer, or the like) is formed over etch stop layer 502 and the etching is performed according to the masking layer 3002. In some embodiments, the etching comprises a dry etching process or some other suitable process. The insulator layer 138 acts as an etch stop layer during the etching to block the etching from reaching bottom electrode 136. In some embodiments, the etching extends into the insulator layer 138 but not through the insulator layer 138.

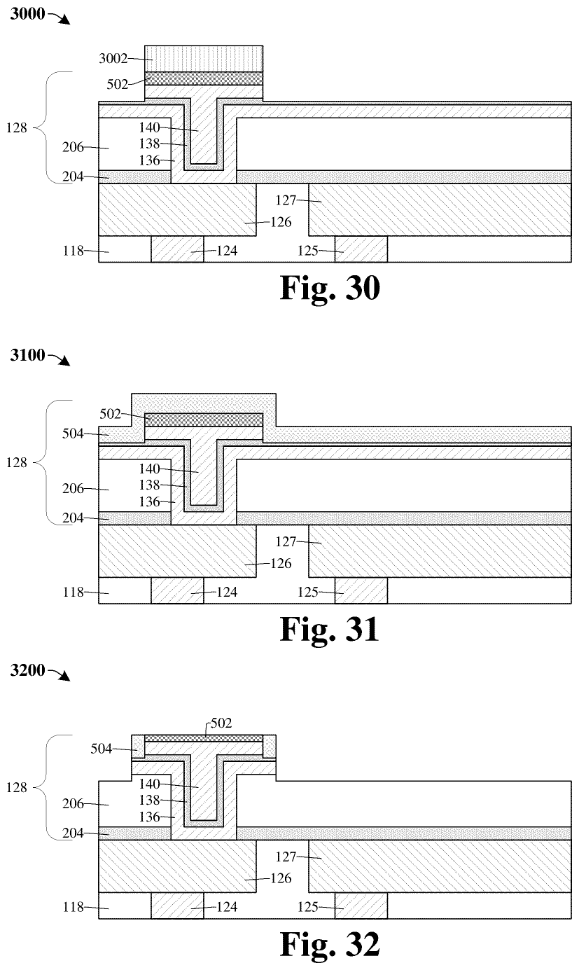

As shown in cross-sectional view 3100 of FIG. 31, a dielectric layer 504 is conformally deposited over insulator layer 138 and etch stop layer 502. In some embodiments, dielectric layer 504 comprises silicon nitride or some other suitable material is deposited by a CVD process, a PVD process, an ALD process, or some other suitable process.

As shown in cross-sectional view 3200 of FIG. 32, dielectric layer 504, the insulator layer 138, and the bottom electrode 136 are etched to delimit the insulator layer 138 and the bottom electrode 136 of the trench capacitor 135. The etching comprises a self-aligned etching process where the bottom electrode 136 and the insulator layer 138 are etched on opposite sides of the top electrode 140 without a masking layer. For example, dielectric layer 504 has a greater thickness along sidewalls of the top electrode 140 and sidewalls of etch stop layer 502 where dielectric layer 504 “steps” from over the insulator layer 138 to over etch stop layer 502 than along a top of etch stop layer 502 and along a top of insulator layer 138. Thus, these “step” regions of dielectric layer 504 remain over the insulator layer 138 and the bottom electrode 136 along the sidewalls of the top electrode 140 and the sidewalls of etch stop layer 502 after the etching due to the increased thickness at these regions. As a result, the insulator layer 138 and the bottom electrode 136 are self-aligned to the top electrode 140.

During the etching, etch stop layer 502 blocks the etching from reaching the top electrode 140. In some embodiments, the etching extends into etch stop layer 502 but not through etch stop layer 502. In some other embodiments, the etching removes etch stop layer 502 from the top electrode 140. In some embodiments, the etching extends into dielectric layer 206 on opposite sides of the trench capacitor 135. In some embodiments, the etching comprises a dry etching process or some other suitable process.

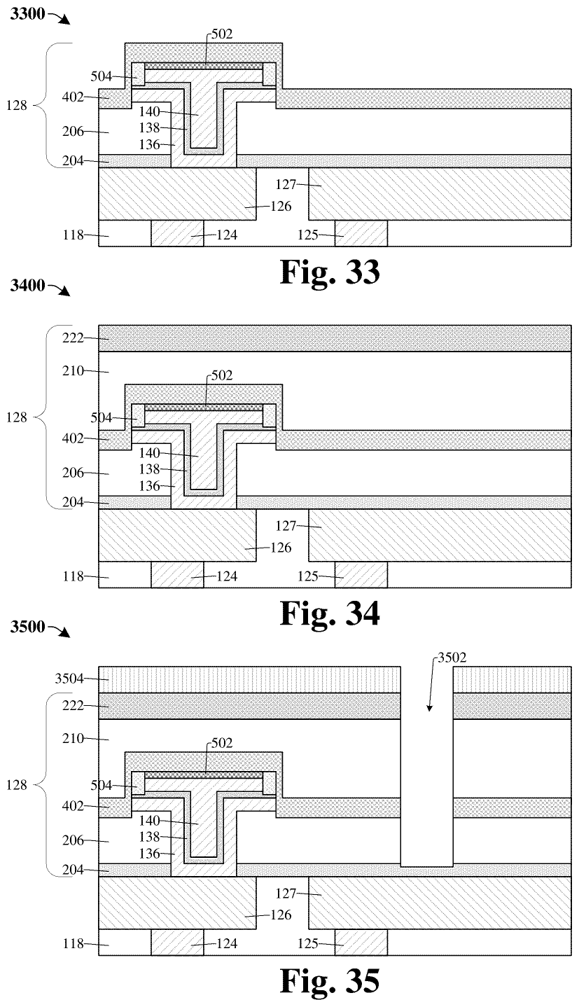

As shown in cross-sectional view 3300 of FIG. 33, an etch stop layer 402 is deposited over dielectric layer 206, dielectric layer 504, and etch stop layer 502. In embodiments where etch stop layer 502 is over the top electrode 140, etch stop layer 402 increases a thickness of the etch stop over top electrode 140. In embodiments where etch stop layer is removed from over the top electrode 140 (e.g., by the etching illustrated in FIG. 32), etch stop layer 402 replenishes the etch stop over the top electrode 140. In some embodiments, etch stop layer 402 comprises silicon nitride or some other suitable material and is deposited by a CVD process, a PVD process, an ALD process, or some other suitable process.

As shown in cross-sectional view 3400 of FIG. 34, dielectric layer 210 is deposited over etch stop layer 402. In some embodiments, a planarization process (e.g., a chemical mechanical planarization (CMP) process or some other suitable process) is performed on dielectric layer 210 after deposition. Further, bonding dielectric layer 222 is deposited over dielectric layer 210.

As shown in cross-sectional view 3500 of FIG. 35, bonding dielectric layer 222, dielectric layer 210, etch stop layer 402, and dielectric layer 206 are etched to form an opening 3502 therein over conductive line 127. In some embodiments, a masking layer 3504 (e.g., a photoresist layer, a hard mask layer, or the like) is formed over bonding dielectric layer 222 and the etching is performed according to the masking layer 3504. In some embodiments, the etching comprises a dry etching process or some other suitable process. Etch stop layer 204 blocks the etching from reaching conductive line 127. In some embodiments, the etching extends into etch stop layer 204 but not through etch stop layer 204.

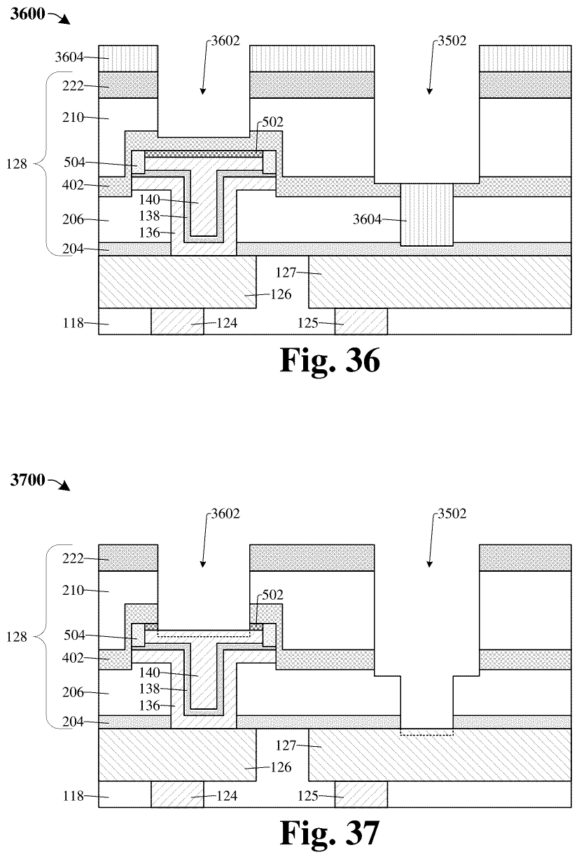

As shown in cross-sectional view 3600 of FIG. 36, bonding dielectric layer 222 and dielectric layer 210 are etched to widen an upper portion of opening 3502 and to form an opening 3602 over the trench capacitor 135. In some embodiments, a masking layer 3604 (e.g., a photoresist layer, a hard mask layer, or the like) is formed over bonding dielectric layer 222 and in a lower portion of opening 3502 and the etching is performed according to the masking layer 3604. In some embodiments, the etching comprises a dry etching process or some other suitable process. Etch stop layer 402 and masking layer 3604 block the etching from extending into dielectric layer 206 at opening 3502. Etch stop layer 402 blocks the etching from reaching the top electrode 140 at opening 3602. In some embodiments, the etching extends into etch stop layer 402 at opening 3502 but not through etch stop layer 402. In some embodiments, the etching extends into etch stop layer 402 at opening 3602 but not through etch stop layer 402 at opening 3602.

As shown in cross-sectional view 3700 of FIG. 37, etch stop layer 204 is etched (e.g., by a subsequent etch stop removal etch) to increase the depth of opening 3502 to uncover conductive line 127. Further, etch stop layer 402 and etch stop layer 502 are etched (e.g., at the same time and with the same etch stop removal etch) to increase the depth of opening 3602 to uncover the top electrode 140. In some embodiments, the etching extends into conductive line 127 at the lower portion of opening 3502. In some embodiments, the etching extends through etch stop layer 402 and into dielectric layer 206 at the upper portion of opening 3502. In some embodiments, the etching extends into the top electrode 140 at opening 3602.

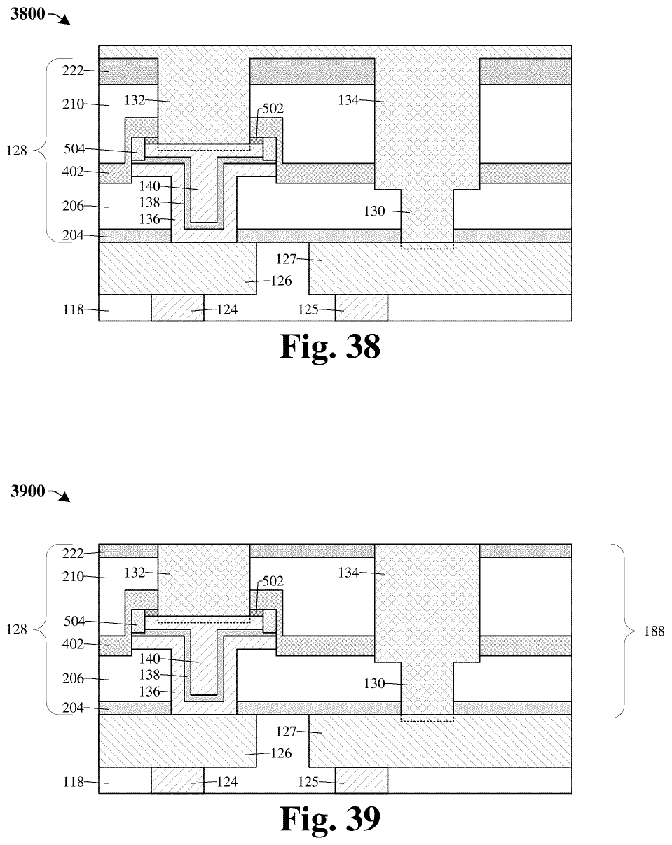

As shown in cross-sectional view 3800 of FIG. 38, a conductive layer is deposited over bonding dielectric layer 222 and in openings 3502, 3602 to form a bonding contact 130 in the lower portion of opening 3502, a bonding pad 134 in the upper portion of opening 3502, and a bonding pad 132 in opening 3602.

As shown in cross-sectional view 3900 of FIG. 39, a planarization process is performed on the conductive layer after deposition to remove the conductive layer from over bonding dielectric layer 222 and to further delimit bonding pads 132, 134. In some embodiments, the planarization process comprises a CMP process, a blanket etching process, or some other suitable process.

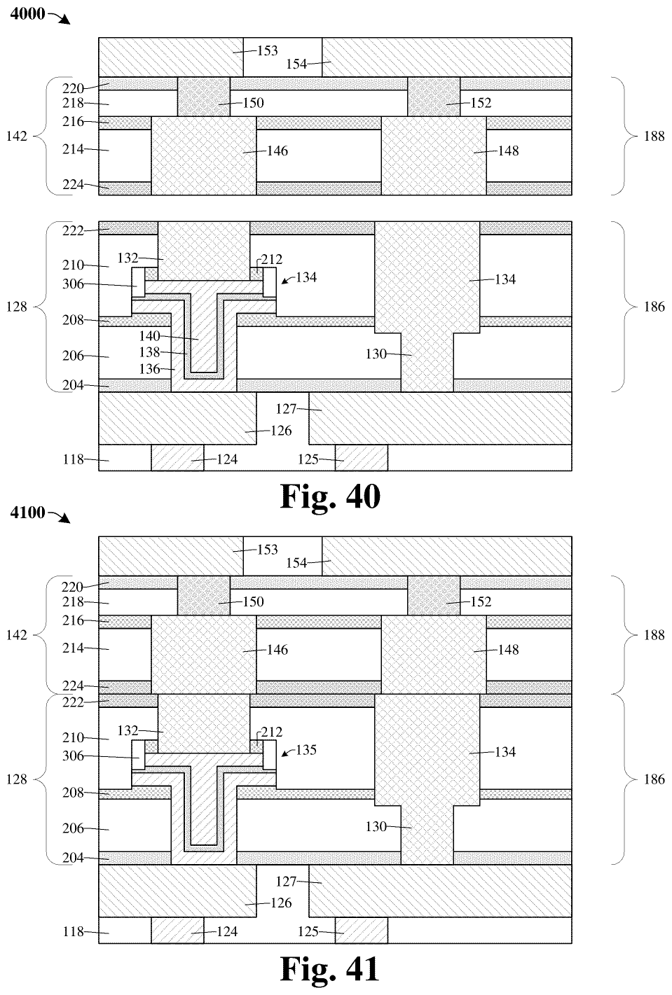

As shown in cross-sectional view 4000 of FIG. 40, the second chip 104 is arranged over the first chip 102 so that bonding pads of the first chip 102 and bonding pads of the second chip 104 are aligned.

As shown in cross-sectional view 4100 of FIG. 41, the first bonding dielectric layer 222 and the second bonding dielectric layer 224 are bonded together by a fusion bonding process, a direct bonding process, or some other suitable process. In some embodiments, the bonding dielectric layers 222, 224 first undergo a room temperature pre-bonding and subsequently undergo further bonding by one or more subsequent annealing processes in which the bonding dielectric layers 222, 224 are heated to improve the strength of the bond.

Further, the bonding pads of the first chip 102 and the bonding pads of the second chip 104 are bonded together by a fusion bonding process, a direct bonding process, or some other suitable process. For example, bonding pad 132 and bonding pad 146 are bonded together, and bonding pad 134 and bonding pad 148 are bonded together. In some embodiments, the bonding pads bond together during the annealing process(es) that is/are performed after the pre-bonding of the bonding dielectric layers 222, 224.

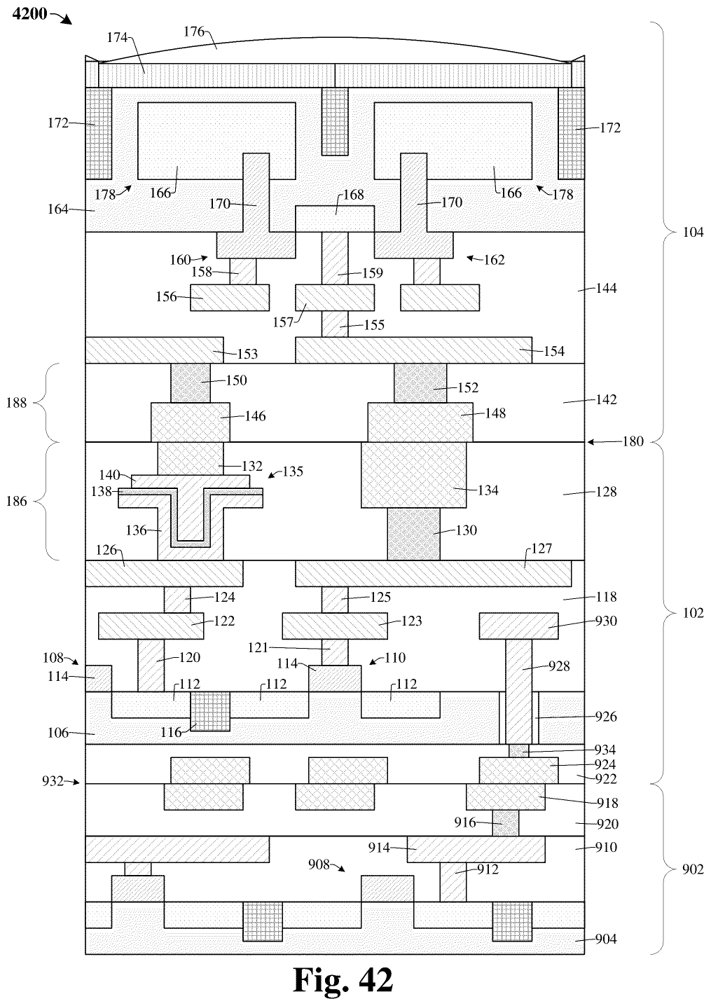

As shown in cross-sectional view 4200 of FIG. 42, in some embodiments, a third chip 902 is bonded along a backside of the first chip 102 by a fusion bonding process, a direct bonding process, or some other suitable process.

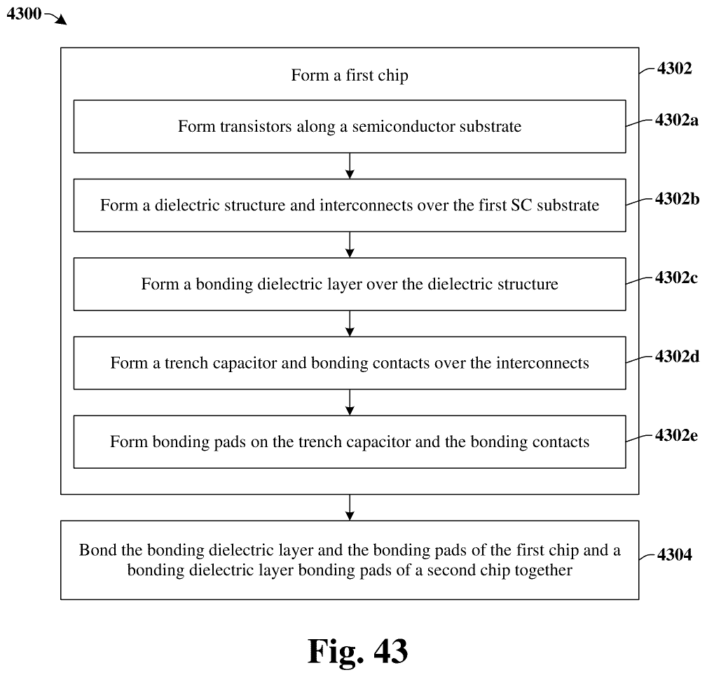

FIG. 43 illustrates a flow diagram of some embodiments of a method 4300 for forming an integrated chip including a trench capacitor in a bonding structure. While method 4300 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At block 4302, form a first chip. FIGS. 13-14 illustrate cross-sectional views 1300-1400 of some embodiments corresponding to block 4302. Block 4302 includes blocks 4302a-4302e.

At block 4302a, form transistors along a semiconductor substrate. FIG. 13 illustrates a cross-sectional view 1300 of some embodiments corresponding to block 4302a.

At block 4302b, form a dielectric structure and interconnects over the first semiconductor substrate. FIG. 14 illustrates a cross-sectional view 1400 of some embodiments corresponding to block 4302b.

At block 4302c, form a bonding dielectric layer over the dielectric structure. FIG. 21 illustrates a cross-sectional view 2100 of some embodiments corresponding to block 4302c. FIG. 34 illustrates a cross-sectional view 3400 of some other embodiments corresponding to block 4302c.

At block 4302d, form a trench capacitor and bonding contacts over the interconnects. FIGS. 16-26 illustrate cross-sectional views 1600-2600 of some embodiments corresponding to block 4302d. FIGS. 28-39 illustrate cross-sectional views 2800-3900 of some other embodiments corresponding to block 4302d.

At block 4302e, form bonding pads on the trench capacitor and the bonding contacts. FIGS. 22-26 illustrate cross-sectional views 2200-2600 of some embodiments corresponding to block 4302e. FIGS. 35-39 illustrate cross-sectional views 3500-3900 of some embodiments corresponding to block 4302e.

At block 4304, bond the bonding dielectric layer and the bonding pads of the first chip and a bonding dielectric layer and bonding pads of a second chip together. FIG. 41 illustrates a cross-sectional view 4100 of some embodiments corresponding to block 4304.

Accordingly, in some embodiments, the present disclosure relates to an integrated chip including a first chip and a second chip bonded to the first chip. The first chip includes a first semiconductor substrate, a first transistor along the first semiconductor substrate, a first conductive interconnect over the first transistor, and a first bonding pad over the first conductive interconnect. The second chip includes a second semiconductor substrate, a second transistor along the second semiconductor substrate, a second conductive interconnect under the second transistor, and a second bonding pad under the second conductive interconnect. The second bonding pad is bonded to the first bonding pad. The first chip further includes a trench capacitor over the first conductive interconnect and under the first bonding pad. The trench capacitor includes a bottom electrode, a top electrode, and an insulator layer between the bottom electrode and the top electrode. The first bonding pad extends from the second bonding pad to the top electrode of the trench capacitor.

In other embodiments, the present disclosure relates to an integrated chip including a first metal interconnect over a first semiconductor substrate. A first dielectric layer is over the first metal interconnect. A trench capacitor extends through the first dielectric layer and over the first dielectric layer. The trench capacitor includes a bottom electrode over the first metal interconnect, a top electrode over the bottom electrode, and an insulator layer between the top electrode and the bottom electrode. A first etch stop layer is over the trench capacitor. A first bonding dielectric layer is over the first etch stop layer. A first bonding pad is over the trench capacitor and extends through the first bonding dielectric layer and the first etch stop layer. A second bonding dielectric layer is over and bonded to the first bonding dielectric layer. A second bonding pad is over the first bonding pad. The second bonding pad extends through the second bonding dielectric layer. A second semiconductor substrate is over the second bonding pad. An upper surface of the first bonding pad is bonded to a lower surface of the second bonding pad. A lower surface of the first bonding pad is on the top electrode of the trench capacitor.

In yet other embodiments, the present disclosure relates to a method for forming an integrated chip. The method includes forming a first transistor along a first semiconductor substrate. A first dielectric structure is formed over the first semiconductor substrate. A first conductive interconnect and a second conductive interconnect are formed within the first dielectric structure. A trench capacitor is formed over the first conductive interconnect. The trench capacitor includes a bottom electrode, a top electrode, and an insulator layer between the bottom electrode and the top electrode. A first bonding contact is formed over the second conductive interconnect and laterally spaced from the trench capacitor. A first bonding pad is formed on the top electrode of the trench capacitor. A second bonding pad is formed on a top of the first bonding contact and laterally spaced from the first bonding pad. A chip is arranged over the first semiconductor substrate. The chip includes a second transistor along a second semiconductor substrate, a second dielectric structure under the second semiconductor substrate, a third conductive interconnect and a fourth conductive interconnect within the second dielectric structure, a third bonding pad under the third conductive interconnect, and a fourth bonding pad under the fourth conductive interconnect and laterally spaced from the third bonding pad. The third bonding pad is bonded to the first bonding pad. The fourth bonding pad is bonded to the second bonding pad.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip comprising:
a first chip comprising a first semiconductor substrate, a first transistor along the first semiconductor substrate, a first conductive interconnect over the first transistor, and a first bonding pad over the first conductive interconnect; and
a second chip bonded to the first chip, the second chip comprising a second semiconductor substrate, a second transistor along the second semiconductor substrate, a second conductive interconnect under the second transistor, and a second bonding pad under the second conductive interconnect, wherein the second bonding pad is bonded to the first bonding pad,
the first chip further comprising a trench capacitor over the first conductive interconnect and under the first bonding pad, the trench capacitor comprising a bottom electrode, a top electrode, and an insulator layer between the bottom electrode and the top electrode, wherein the first bonding pad extends from the second bonding pad to the top electrode of the trench capacitor.

2. The integrated chip of claim 1, wherein the bottom electrode of the trench capacitor extends from the insulator layer to the first conductive interconnect.

3. The integrated chip of claim 1, the first chip further comprising a bonding contact laterally spaced from the trench capacitor, and a third bonding pad over the bonding contact and laterally spaced from the first bonding pad and the trench capacitor.

4. The integrated chip of claim 3, wherein the bonding contact meets the third bonding pad above a bottom of the trench capacitor and below a top of the trench capacitor, and wherein the top electrode meets the first bonding pad above a bottom of the third bonding pad and below a top of the third bonding pad.

5. The integrated chip of claim 1, the second chip further comprising a photodetector along the second semiconductor substrate.

6. The integrated chip of claim 5, further comprising:
a third chip bonded to the first chip, the third chip comprising a third semiconductor substrate, a third transistor along the third semiconductor substrate, a third conductive interconnect over the third transistor, and a third bonding pad over the third conductive interconnect,
wherein the first chip further comprises a fourth bonding pad between the first semiconductor substrate and the third chip, wherein the fourth bonding pad is bonded to the third bonding pad.

7. The integrated chip of claim 1, the first chip further comprising a photodetector along the first semiconductor substrate.

8. An integrated chip comprising:
a first metal interconnect over a first semiconductor substrate;
a first dielectric layer over the first metal interconnect;
a trench capacitor extending through the first dielectric layer and over the first dielectric layer, the trench capacitor comprising a bottom electrode over the first metal interconnect, a top electrode over the bottom electrode, and an insulator layer between the top electrode and the bottom electrode;
a first etch stop layer over the trench capacitor;
a first bonding dielectric layer over the first etch stop layer;
a first bonding pad over the trench capacitor and extending through the first bonding dielectric layer and the first etch stop layer;
a second bonding dielectric layer over and bonded to the first bonding dielectric layer;
a second bonding pad over the first bonding pad, the second bonding pad extending through the second bonding dielectric layer; and
a second semiconductor substrate over the second bonding pad,
wherein an upper surface of the first bonding pad is bonded to a lower surface of the second bonding pad, and wherein a lower surface of the first bonding pad is on the top electrode of the trench capacitor.

9. The integrated chip of claim 8, further comprising:
a second metal interconnect laterally spaced from the first metal interconnect;
a bonding contact over the second metal interconnect, laterally spaced from the trench capacitor, and extending through the first dielectric layer;
a third bonding pad over the bonding contact, laterally spaced from the first bonding pad, and extending through the first bonding dielectric layer; and
a fourth bonding pad over and bonded to the third bonding pad, laterally spaced from the second bonding pad, and extending through the second bonding dielectric layer.

10. The integrated chip of claim 9, wherein the trench capacitor extends from below a top of the bonding contact and below a bottom of the third bonding pad to above the top of the bonding contact and above the bottom of the third bonding pad, and wherein the third bonding pad extends from below a top of the top electrode and below a bottom of the first bonding pad to above the top of the top electrode and above the bottom of the first bonding pad.

11. The integrated chip of claim 8, wherein the first dielectric layer comprises a first dielectric, the first etch stop layer comprises a second dielectric, different than the first dielectric, the first bonding dielectric layer comprises a third dielectric, different than the first dielectric and the second dielectric, and the second bonding dielectric layer comprises a fourth dielectric, different than the first dielectric and the second dielectric.

12. The integrated chip of claim 8, wherein the first etch stop layer extends along a top surface of the top electrode, and wherein the first bonding pad extends through the first etch stop layer to the top surface of the top electrode.

13. The integrated chip of claim 8, further comprising:
a second dielectric layer between the first dielectric layer and the first bonding dielectric layer, and between the first etch stop layer and the first bonding dielectric layer, wherein the trench capacitor extends above a bottom of the second dielectric layer, and wherein the first bonding pad extends through the second dielectric layer; and
a second etch stop layer between the first dielectric layer and the second dielectric layer, wherein the trench capacitor extends through the second etch stop layer and over the second etch stop layer.

14. The integrated chip of claim 13, further comprising:
a third dielectric layer laterally between the second dielectric layer and the top electrode, and laterally between the second dielectric layer and the first etch stop layer.

15. The integrated chip of claim 8, further comprising:
a second dielectric layer between the first etch stop layer and the first bonding dielectric layer, wherein the first etch stop layer is between the first dielectric layer and the second dielectric layer, wherein the first etch stop layer is between the second dielectric layer and the trench capacitor, wherein the trench capacitor is extends above a bottom of the second dielectric layer and above a bottom of the first etch stop layer, and wherein the first bonding pad extends through the second dielectric layer.

16. The integrated chip of claim 8, further comprising:
a second etch stop layer vertically between the first etch stop layer and the top electrode; and
a third dielectric layer laterally between the first etch stop layer and the top electrode and laterally between the first etch stop layer and the second etch stop layer.

17. The integrated chip of claim 8, further comprising:
a third bonding pad over the trench capacitor, laterally spaced from the first bonding pad, and extending through the first bonding dielectric layer; and
a fourth bonding pad over and bonded to the third bonding pad, laterally spaced from the second bonding pad, and extending through the second bonding dielectric layer,
wherein the third bonding pad extends from the fourth bonding pad to the bottom electrode.

18. A method for forming an integrated chip, the method comprising:
forming a first transistor along a first semiconductor substrate, a first dielectric structure over the first semiconductor substrate, and a first conductive interconnect and a second conductive interconnect within the first dielectric structure;
forming a trench capacitor over the first conductive interconnect, the trench capacitor comprising a bottom electrode, a top electrode, and an insulator layer between the bottom electrode and the top electrode;
forming a first bonding contact over the second conductive interconnect and laterally spaced from the trench capacitor;
forming a first bonding pad on the top electrode of the trench capacitor;
forming a second bonding pad on a top of the first bonding contact and laterally spaced from the first bonding pad;
arranging a chip over the first semiconductor substrate, the chip comprising a second transistor along a second semiconductor substrate, a second dielectric structure under the second semiconductor substrate, a third conductive interconnect and a fourth conductive interconnect within the second dielectric structure, a third bonding pad under the third conductive interconnect, and a fourth bonding pad under the fourth conductive interconnect and laterally spaced from the third bonding pad; and
bonding the third bonding pad to the first bonding pad and bonding the fourth bonding pad to the second bonding pad.

19. The method of claim 18, further comprising:
forming a first bonding dielectric layer over the trench capacitor, wherein the first bonding pad extends between through the first bonding dielectric layer and the second bonding pad extends through the first bonding dielectric layer, and wherein the chip comprises a second bonding dielectric layer extending between the third bonding pad and the fourth bonding pad; and
bonding the second bonding dielectric layer to the first bonding dielectric layer.

20. The method of claim 19, wherein forming the first bonding pad on the top electrode of the trench capacitor comprises etching the first bonding dielectric layer to uncover an upper surface of the top electrode and depositing a metal directly on the upper surface of the top electrode.
